(19) United States
(12) Patent Application Publication
(10) Pub. No.: US 2023/0019266 A1
(43) Pub. Date: Jan. 19, 2023

(54) THERMOELECTRIC MODULE AND A VEHICLE INCLUDING THE SAME

(71) Applicants: HYUNDAI MOTOR COMPANY, Seoul (KR); KIA CORPORATION, Seoul (KR); LT METAL CO., LTD., Incheon (KR)

(72) Inventors: Byung Wook Kim, Seongnam-si (KR); Min Jae Lee, Seongnam-si (KR); Byung Jin Hwang, Incheon (KR); Seung Jin Yang, Incheon (KR); Byeong Hoon Yeon, Incheon (KR); Kyoung Hyun Son, Incheon (KR); Bong Jung Jang, Incheon (KR); Tae Hee Lee, Incheon (KR); Seung Ho Yang, Incheon (KR); Joo Hyeon Park, Incheon (KR); Jung Ku Park, Incheon (KR)

(73) Assignees: HYUNDAI MOTOR COMPANY, Seoul (KR); KIA CORPORATION, Seoul (KR); LT METAL CO., LTD., Incheon (KR)

(21) Appl. No.: 17/584,146

(22) Filed: Jan. 25, 2022

(30) Foreign Application Priority Data
Jul. 13, 2021 (KR) 10-2021-0091788

(51) Int. Cl. H01L 35/32; H01L 35/02

(52) U.S. Cl. CPC H01L 35/32; H01L 35/02; H01L 35/34

(57) ABSTRACT

A thermoelectric module includes a first electrode, a first oxidation preventing layer, a plurality of first bonding layers containing silver (Ag), a second oxidation preventing layer, a first plating layer, a thermoelectric element, a second plating layer, a third oxidation preventing layer, a second bonding layer containing silver (Ag), a fourth oxidation preventing layer, and a second electrode.

### CROSS-REFERENCE TO RELATED APPLICATION

This application claims the benefit of priority to Korean Patent Application No. 10-2021-0091788, filed in the Korean Intellectual Property Office on Jul. 13, 2021, the entire contents of which are incorporated herein by reference.

### TECHNICAL FIELD

The present disclosure relates to a thermoelectric module having excellent interlayer bonding strength and excellent thermal durability as thermal stress generated when exposed to heat is reduced and relates to a vehicle including the same.

### BACKGROUND

The thermoelectric effect refers to a reversible and direct energy conversion between heat and electricity. The thermoelectric effect, which is a phenomenon caused by movements of electrons and holes inside a material, is divided into the Peltier effect and the Seebeck effect. The Peltier effect is applied to a cooling field, using a temperature difference between both ends formed by a current applied from the outside. The Seebeck effect is applied to a power generation field, using an electromotive force generated from the temperature difference between the both ends of the material.

Recently, research on a thermoelectric module is being actively conducted to solve problems such as a sharp increase in a cost of energy-related resources, serious environmental pollution, and the like. In general, the thermoelectric module includes an N-type thermoelectric element and a P-type thermoelectric element that have opposite polarities and are alternately disposed, and electrodes electrically connecting the thermoelectric elements to each other. Such thermoelectric module uses a material with a bonding property to connect a substrate as a skeleton to each electrode. In particular, when using a metal copper clad laminate (MCCL) substrate, there is a layer that bonds the metallic substrate to the electrode. In a high-temperature region, such layer has conductivity, so that there is a problem that electrodes adjacent to each other are short-circuited.

In one example, when a bonding force between each electrode and the substrate is insufficient, there was a problem that cracks occur in the substrate. This is because thermal stress resulted from thermal expansion is greater than the bonding force between the electrode and the substrate when exposed to high-temperature for a long period of time. In addition, as described above, the thermoelectric module in which the cracks have occurred has a problem that an output thereof is reduced, and thus an efficiency thereof is lowered.

Therefore, there is a need for research and development for a thermoelectric module having excellent interlayer bonding strength and excellent thermal durability as the thermal stress generated when exposed to the heat is reduced. There is also a need to provide a vehicle including the same.

### SUMMARY

The present disclosure has been made to solve the above-mentioned problems occurring in the prior art while advantages achieved by the prior art are maintained intact.

An aspect of the present disclosure provides a thermoelectric module having excellent interlayer bonding strength, in particular, excellent bonding strength between an electrode and a substrate, and excellent thermal durability as thermal stress generated when exposed to heat is reduced. The present disclosure also provides a vehicle including the same.

The technical problems to be solved by the present inventive concept are not limited to the aforementioned problems. Any other technical problems not mentioned herein should be clearly understood from the following description by those having ordinary skill in the art to which the present disclosure pertains.

According to an aspect of the present disclosure, a thermoelectric module includes a first electrode;

a first oxidation preventing layer stacked on one surface of the first electrode;

a plurality of first bonding layers stacked on the first oxidation preventing layer and containing silver (Ag);

a second oxidation preventing layer stacked on each first bonding layer;

a first plating layer stacked on each second oxidation preventing layer;

a thermoelectric element stacked on each first plating layer;

a second plating layer stacked on each thermoelectric element;

a third oxidation preventing layer stacked on each second plating layer;

a second bonding layer stacked on each third oxidation preventing layer and containing silver (Ag);

a fourth oxidation preventing layer stacked on each second bonding layer; and

a second electrode stacked on each fourth oxidation preventing layer.

Each of the first plating layer and the second plating layer includes a nickel layer, a first alloy layer stacked on the nickel layer and including a nickel-cobalt alloy, and a second alloy layer stacked on the first alloy layer and including a nickel-phosphorus alloy.

According to another aspect of the present disclosure, a vehicle includes the thermoelectric module.

### BRIEF DESCRIPTION OF THE DRAWINGS

The above and other objects, features, and advantages of the present disclosure should be more apparent from the following detailed description taken in conjunction with the accompanying drawings:

FIGS. 1-7 are cross-sectional views of a thermoelectric module according to an embodiment of the present disclosure;

FIG. 8 is a cross-sectional view of a thermoelectric module of Example 1;

FIG. 9 is a result of measuring a voltage, a current, and a power during a thermal shock test of a thermoelectric module of Example 1;

FIG. 10 is a scanning electron microscope (SEM) photograph of an interface of each layer after a thermal shock test of a thermoelectric module of Example 1;

FIG. 11 is a result of measuring a voltage, a current, and a power during a thermal shock test of a thermoelectric module of Comparative Example 1;

FIG. 12 is a SEM photograph of an interface of each layer after a thermal shock test of a thermoelectric module of Comparative Example 1;

FIG. 13 is a SEM photograph of an interface of each layer after a thermal shock test of a thermoelectric module of Comparative Example 2;

FIG. 14 is a SEM photograph of an interface of each layer after a thermal shock test of a thermoelectric module of Comparative Example 3; and

FIG. 15 shows Energy-Dispersive X-Ray Spectroscopy (EDS) photographs after a thermal shock test of a thermoelectric module of Comparative Example 3.

### DETAILED DESCRIPTION

In the present specification, when a certain portion “includes” a certain component, this means that the certain portion may further include other components without excluding other components unless otherwise stated.

In the present specification, when a first member is located on “on” or “on one surface” of a second member, this includes not only a case in which the first member is in contact with the second member, but also a case in which a third member exists between the two members.

### Thermoelectric Module

A thermoelectric module according to the present disclosure has a form in which a first electrode, a first oxidation preventing layer, a plurality of first bonding layers, a second oxidation preventing layer, a first plating layer, a thermoelectric element, a second plating layer, a third oxidation preventing layer, a second bonding layer, a fourth oxidation preventing layer, and a second electrode are sequentially stacked.

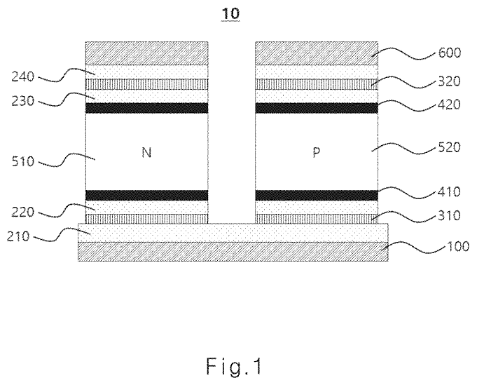

Referring to FIG. 1, a thermoelectric module 10 according to the present disclosure has a form in which a first electrode 100, a first oxidation preventing layer 210, a plurality of first bonding layers 310, a second oxidation preventing layer 220, a first plating layer 410, thermoelectric elements 510 and 520, a second plating layer 420, a third oxidation preventing layer 230, a second bonding layer 320, a fourth oxidation preventing layer 240, and a second electrode 600 are sequentially stacked.

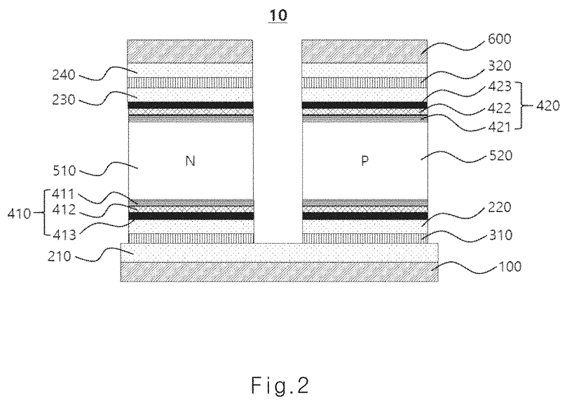

In this connection, each of the first plating layer and the second plating layer includes a nickel layer, a first alloy layer including a nickel-cobalt alloy, and a second alloy layer including a nickel-phosphorus alloy. For example, referring to FIG. 2, the thermoelectric module 10 according to the present disclosure has a form in which the first electrode 100, the first oxidation preventing layer 210, the plurality of first bonding layers 310, the second oxidation preventing layer 220, a second alloy layer 413, a first alloy layer 412, a nickel layer 411, the thermoelectric elements 510 and 520, a nickel layer 421, a first alloy layer 422, a second alloy layer 423, the third oxidation preventing layer 230, the second bonding layer 320, the fourth oxidation preventing layer 240, and the second electrode 600 are sequentially stacked.

### First Electrode and Second Electrode

Materials of the first electrode and the second electrode are not particularly limited as long as they are commonly used for electrodes in the art. For example, the first electrode and the second electrode may be made of the same material or different materials. Each of the first electrode and the second electrode may independently contain at least one selected from a group consisting of aluminum (Al), zinc (Zn), copper (Cu), nickel (Ni), silver (Ag), or chromium (Cr). Specifically, each of the first electrode and the second electrode may independently contain at least one selected from a group consisting of aluminum (Al), zinc (Zn), copper (Cu), and nickel (Ni), and may further contain gold (Au), silver (Ag), titanium (Ti), or the like.

In addition, sizes of the first electrode and the second electrode may also be variously adjusted. For example, each of the first electrode and the second electrode may independently have a thickness in a range from 10 to 500 μm or a range from 10 to 200 μm. When the thickness of each of the first electrode and the second electrode is less than the above range, there may be a problem that a resistance of the electrode increases, and thus a power efficiency decreases. When the thickness of each of the first electrode and the second electrode exceeds the above range, there may be a problem that thermal expansion of the electrode becomes excessive.

The first electrode and the second electrode may be patterned in a shape commonly applied in a field of thermoelectric module and may not be particularly limited in shape.

The first electrode and the second electrode may respectively include a plurality of first electrodes and a plurality of second electrodes. Adjacent first electrodes or adjacent second electrodes may not be directly in contact with each other by being spaced apart from each other by a predetermined distance.

### First Oxidation Preventing Layer, Second Oxidation Preventing Layer, Third Oxidation Preventing Layer, and Fourth Oxidation Preventing Layer

The first oxidation preventing layer, the second oxidation preventing layer, the third oxidation preventing layer, and the fourth oxidation preventing layer prevent oxidation of the electrode and/or the plating layer and improve a bonding force between the electrode and/or the plating layer and the bonding layer.

Each of the first oxidation preventing layer to the fourth oxidation preventing layer may independently contain at least one selected from a group consisting of gold (Au), silver (Ag), titanium (Ti), chromium (Cr), nickel (Ni), tantalum (Ta), platinum (Pt), or aluminum (Al). Specifically, each of the first oxidation preventing layer to the fourth oxidation preventing layer may independently contain gold (Au). When each of the first oxidation preventing layer to the fourth oxidation preventing layer contains gold (Au), wettability of the bonding layer containing silver (Ag) may be improved to improve an interlayer bonding strength.

In addition, each of the first oxidation preventing layer to the fourth oxidation preventing layer may independently have a thickness in a range from 5 to 500 nm or a range from 100 to 300 nm. When the thickness of each of the first oxidation preventing layer to the fourth oxidation preventing layer is less than the above range, it may not be possible to obtain an effect of preventing oxidation of the electrode and/or the plating layer, which is an effect of the oxidation preventing layer and obtain an effect of improving the bonding force with the bonding layer. When the thickness of each of the first oxidation preventing layer to the fourth oxidation preventing layer exceeds the above range, there may be a problem that economic efficiency is lowered because an improvement in the effect is insufficient compared to the thickness.

### First Bonding Layer and Second Bonding Layer

The first bonding layer and the second bonding layer serve to improve a bonding force between the oxidation preventing layers.

Each of the first bonding layer and the second bonding layer may contain silver (Ag). The first bonding layer and the second bonding layer may respectively include a plurality of first bonding layers and a plurality of second bonding layers. When the first bonding layer and the second bonding layer contain silver (Ag), an alloy that generates cracks is not generated even when exposed to heat for a long period of time, and thus durability of the thermoelectric module including the same may be improved. In one example, when the first bonding layer and the second bonding layer respectively have compositions that do not contain silver (Ag), an alloy having a different thermal expansion coefficient is created with an oxidation preventing layer in contact with the bonding layer when the thermoelectric module is exposed to high-temperature. Thus, a pore and/or a secondary phase may be created. In addition, when the pore and/or the secondary phase created as such are exposed to the high-temperatures for a long period of time, the cracks may occur, which may cause a problem of deteriorating bonding of the layers.

Specifically, each of the first bonding layer and the second bonding layer may be made of silver (Ag). When the first bonding layer and the second bonding layer are made of silver (Ag), as a difference in thermal expansion between the electrode and the thermoelectric element has an intermediate value, thermal stress is reduced. Thus, the durability of the thermoelectric module may be improved.

In addition, each of the first bonding layer and the second bonding layer may independently have a thickness in a range from 5 to 500 nm or a range from 10 to 100 nm. When the thickness of each of the first bonding layer and the second bonding layer is less than the above range, there may be a problem of peeling resulted from insufficient bonding force between the oxidation preventing layers. When the thickness of each of the first bonding layer and the second bonding layer exceeds the above range, there may be a problem that the economic efficiency is lowered because the improvement in the effect is insufficient compared to the thickness of the bonding layer.

Each of the first bonding layer and the second bonding layer may independently include fine particles having an average diameter in a range from 10 to 600 nm or a range from 10 to 500 nm, and coarse particles having an average diameter in a range from 1 to 100 μm or a range from 5 to 80 μm. In addition, each of the first bonding layer and the second bonding layer may independently include the fine particles and the coarse particles in a weight ratio range from 1:1.3 to 3.0 or from 1:1.5 to 2.5.

### First Plating Layer and Second Plating Layer

The first plating layer and the second plating layer suppress thermal diffusion occurred by a difference in a thermal expansion coefficient in a vertical direction between the layers to prevent separation between the layers by the thermal stress.

Each of the first plating layer and the second plating layer includes the nickel layer, the first alloy layer stacked on the nickel layer and including the nickel-cobalt alloy, and the second alloy layer stacked on the first alloy layer and including the nickel-phosphorus alloy. Referring to FIG. 2, the nickel layer 411 and 421, the first alloy layer 412 and 422 stacked on the nickel layer 411 and 421, and the second alloy layer 413 and 423 stacked on the first alloy layer 412 and 422 may be included on the thermoelectric element. For example, the first alloy layer may include the nickel-cobalt (Ni—Co) alloy, and the second alloy layer may include the nickel-phosphorus (Ni—P) alloy.

In addition, each of the first plating layer and the second plating layer may independently include the nickel layer having a thickness in a range from 0.001 to 1 μm or a range from 0.01 to 0.1 μm, the first alloy layer having a thickness in a range from 0.1 to 15 μm or a range from 0.1 to 5 μm, and the second alloy layer having a thickness in a range from 0.6 to 20 μm or a range from 1.0 to 10 μm.

When the thickness of each of the nickel layer, the first alloy layer, and the second alloy layer is less than each of the above ranges, there may be a problem that separation between the thermoelectric element and the bonding layer occurs because an effect of preventing heat diffusion between the layers is insufficient. When the thickness of each of the nickel layer, the first alloy layer, and the second alloy layer exceeds each of the above ranges, there may be a problem that the economic efficiency is lowered because the improvement in the effect is insufficient compared to the thickness of each layer.

Each of the first plating layer and the second plating layer may independently have the nickel layer having a thickness in a range from 0.1 to 5 thickness %, the first alloy layer having a thickness in a range from 1 to 90 thickness 5, and the second alloy layer having a thickness in a range from 1 to 90 thickness % based on a total thickness of the plating layer. Specifically, each of the first plating layer and the second plating layer may independently have the nickel layer having a thickness in a range from 0.1 to 2 thickness % or a range from 0.5 to 1.5 thickness %, the first alloy layer having a thickness in a range from 1 to 50 thickness % or a range from 10 to 30 thickness %, and the second alloy layer having a thickness in a range from 50 to 90 thickness % or a range from 65 to 85 thickness % based on a total thickness of the plating layer.

### Thermoelectric Element

In the thermoelectric module, in a manner in which the thermoelectric element is formed on the first electrode and the second electrode is formed on the thermoelectric element, the plurality of first electrodes, the plurality of thermoelectric elements, and the plurality of second electrodes may be connected to each other in series.

The thermoelectric element includes a plurality of P-type thermoelectric elements 520 and a plurality of N-type thermoelectric elements 510. Such a plurality of pairs of N-type and P-type thermoelectric elements may be disposed in a manner in which each P-type thermoelectric element and each N-type thermoelectric element are alternately disposed in one direction. As described above, top surfaces and bottom surfaces of the P-type thermoelectric element 520 and the N-type thermoelectric element 510 adjacent to each other in said one direction may be electrically connected in series with the second electrode 600 and the first electrode 100, respectively. In this connection, a pair of the P-type thermoelectric element 520 and the N-type thermoelectric element 510 electrically connected to each other may form a unit cell. Each of such thermoelectric elements 510 and 520 may include a thermoelectric semiconductor.

The thermoelectric semiconductor included in each of the thermoelectric elements 510 and 520 may be made of a material common in the art that generates a temperature difference when electricity is applied to both ends thereof or generates the electricity when the temperature difference is generated at both ends thereof. For example, the thermoelectric semiconductor may contain at least one selected from a group consisting of a transition metal, a rare earth element, a group 13 element, a group 14 element, a group 15 element, and a group 16 element. Examples of the rare earth element may include Y, Ce, La, and the like, examples of the transition metal include Ti, Zr, Hf, V, Nb, Ta, Cr, Mo, W, Mn, Fe, Co, Ni, Cu, Zn, Ag, Re, and the like. In addition, examples of the group 13 element may include B, Al, Ga, In, and the like, examples of the group 14 element may include C, Si, Ge, Sn, Pb, and the like, examples of the group 15 element may include P, As, Sb, Bi, and the like, and examples of the group 16 element may include S, Se, Te, and the like.

For example, the thermoelectric semiconductor may contain at least one selected from a group consisting of bismuth (Bi), telerium (Te), cobalt (Co), samarium (Sb), indium (In), and cerium (Ce). Specifically, examples of the thermoelectric semiconductor may include a Bi—Te-based thermoelectric semiconductor, a Co—Sb-based thermoelectric semiconductor, a Pb—Te-based thermoelectric semiconductor, a Ge—Tb-based thermoelectric semiconductor, a Si—Ge-based thermoelectric semiconductor, a Sb—Te-based thermoelectric semiconductor, a Sm—Co-based thermoelectric semiconductor, a transition metal silicide-based thermoelectric semiconductor, a Skuttrudite-based thermoelectric semiconductor, a silicide-based thermoelectric semiconductor, a Half Heusler thermoelectric semiconductor, or combinations thereof. Examples of the Bi—Te-based thermoelectric semiconductor may include a (Bi,Sb)₂(Te,Se)₃-based thermoelectric semiconductor in which Sb and Se are used as dopants, and examples of the Co—Sb-based thermoelectric semiconductor may include a CoSb₃-based thermoelectric semiconductor. Further, examples of the Sb—Te-based thermoelectric semiconductor may include AgSbTe₂ and CuSbTe₂, and examples of the Pb—Te-based thermoelectric semiconductor may include PbTe, (PbTe)mAgSbTe₂, and the like.

In addition, the thermoelectric semiconductor may have particles having a size typically used in the art, for example, an average particle diameter in a range from 0.01 to 100 μm.

The thermoelectric semiconductor may be manufactured in various methods commonly used in the art and may not be particularly limited. For example, the thermoelectric semiconductor may be manufactured by performing a melt-spinning method, a gas atomization method, or the like, and then performing a press sintering method. In addition, a thermoelectric pellet including the P-type thermoelectric element 520 and the N-type thermoelectric element 510 may be processed into a predetermined shape, for example, a rectangular parallelepiped shape using a method such as cutting or the like.

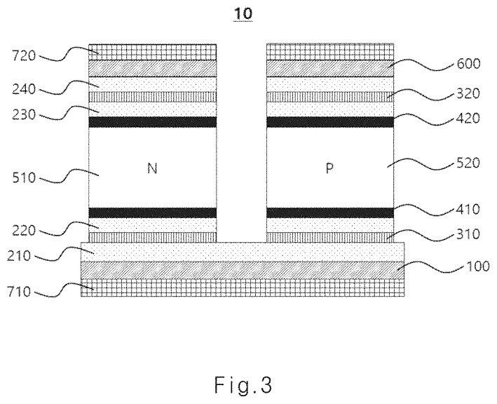

The thermoelectric module may additionally include a first substrate stacked on the other surface of the first electrode and a second substrate stacked on the second electrode. Referring to FIG. 3, the thermoelectric module 10 according to the present disclosure may have a form in which a first substrate 710, the first electrode 100, the first oxidation preventing layer 210, the plurality of first bonding layers 310, the second oxidation preventing layer 220, the first plating layer 410, the thermoelectric element 510 and 520, the second plating layer 420, the third oxidation preventing layer 230, the second bonding layer 320, the fourth oxidation preventing layer 240, the second electrode 600, and a second substrate 720 are sequentially stacked.

### First Substrate and Second Substrate

The first substrate 710 and the second substrate 720, which are conductive substrates, serve to cause an exothermic or endothermic reaction when power is applied to the thermoelectric module 10.

Referring to FIGS. 1-3, the first substrate 710 may be formed as a single body, and the second substrate 720 may include a plurality of second substrates. The number of second substrates 720 may correspond to the number of second electrodes 600, and each second substrate 720 may be formed on each second electrode 600.

Each of the first substrate and the second substrate may be independently selected from a group consisting of a metal copper clad laminate (MCCL) substrate including an insulating resin layer and a metal layer stacked on the resin layer and a direct bonded copper (DBC) substrate including an insulating layer. Specifically, the first substrate may be the MCCL substrate or the DBC substrate, and the second substrate may be the MCCL substrate or the DBC substrate.

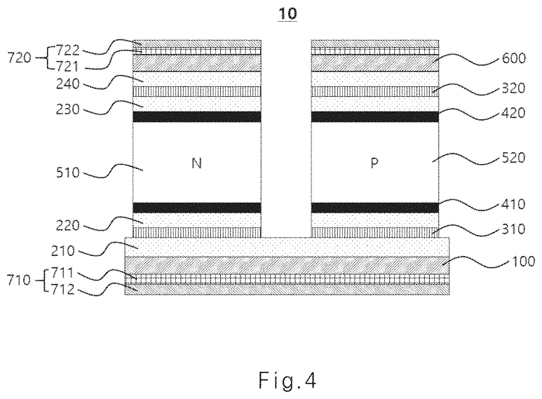

For example, referring to FIG. 4, the thermoelectric module 10 may have a form in which a metal layer 712, an insulating resin layer 711, the first electrode 100, the first oxidation preventing layer 210, the plurality of first bonding layers 310, the second oxidation preventing layer 220, the first plating layer 410, the thermoelectric elements 510 and 520, the second plating layer 420, the third oxidation preventing layer 230, the second bonding layer 320, the fourth oxidation preventing layer 240, the second electrode 600, an insulating resin layer 721, and a metal layer 722 are sequentially stacked. As such, the first substrate 710 and the second substrate 720 may be the MCCL substrate including the resin layer and the metal layer.

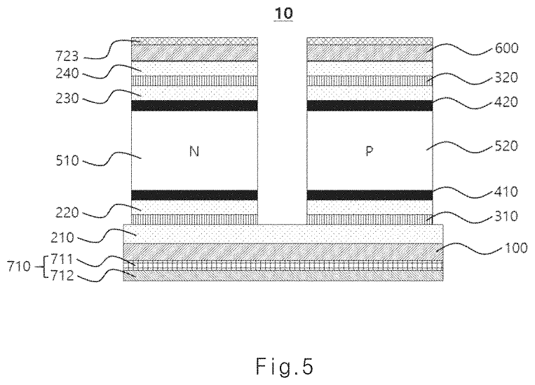

Referring to FIG. 5, the thermoelectric module 10 may have a form in which the metal layer 712, the insulating resin layer 711, the first electrode 100, the first oxidation preventing layer 210, the plurality of first bonding layers 310, the second oxidation preventing layer 220, the first plating layer 410, the thermoelectric elements 510 and 520, the second plating layer 420, the third oxidation preventing layer 230, the second bonding layer 320, the fourth oxidation preventing layer 240, the second electrode 600, and an insulating layer 723 are sequentially stacked. As such, the first substrate 710 may be the MCCL substrate including the resin layer and the metal layer, and the second substrate 720 may be the DBC substrate including the insulating layer.

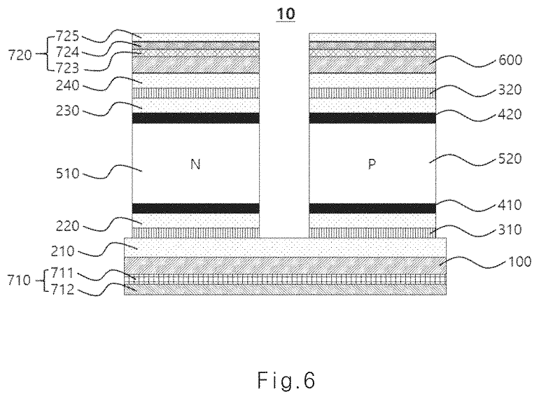

Referring to FIG. 6, the thermoelectric module 10 may have a form in which the metal layer 712, the insulating resin layer 711, the first electrode 100, the first oxidation preventing layer 210, the plurality of first bonding layers 310, the second oxidation preventing layer 220, the first plating layer 410, the thermoelectric elements 510 and 520, the second plating layer 420, the third oxidation preventing layer 230, the second bonding layer 320, the fourth oxidation preventing layer 240, the second electrode 600, the insulating layer 723, a conductive layer 724, and a fifth oxidation preventing layer 725 are sequentially stacked. As such, the first substrate 710 may be the MCCL substrate including the resin layer and the metal layer, and the second substrate 720 may be the DBC substrate including the insulating layer, the conductive layer, and the oxidation preventing layer.

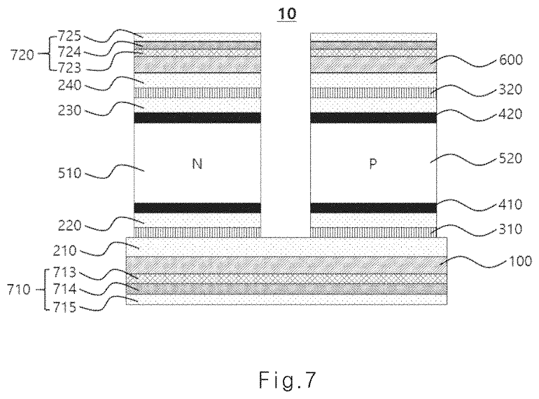

Referring to FIG. 7, the thermoelectric module 10 may have a form in which a sixth oxidation preventing layer 715, a conductive layer 714, an insulating layer 713, the first electrode 100, the first oxidation preventing layer 210, the plurality of first bonding layers 310, the second oxidation preventing layer 220, the first plating layer 410, the thermoelectric elements 510 and 520, the second plating layer 420, the third oxidation preventing layer 230, the second bonding layer 320, the fourth oxidation preventing layer 240, the second electrode 600, the insulating layer 723, the conductive layer 724, and the fifth oxidation preventing layer 725 are sequentially stacked. As such, the first substrate 710 and the second substrate 720 may be the DBC substrate including the insulating layer, the conductive layer, and the oxidation preventing layer.

The resin layers 711 and 721 may contain at least one selected from a group consisting of alumina and an epoxy resin, and may contain, for example, alumina and the epoxy resin. In this case, the epoxy resin does not contain a halogen element and may contain at least two epoxy groups in one molecule. In addition, the resin layers 711 and 721 may have an average thickness in a range from 0.01 to 0.5 mm or a range from 0.01 to 0.20 mm.

The metal layers 712 and 722 may be made of a common conductive metal material. For example, the metal layers 712 and 722 may contain at least one selected from a group consisting of aluminum (Al), copper (Cu), nickel (Ni), silver (Ag), and chromium (Cr). In addition, the metal layers 712 and 722 may have an average thickness in a range from 0.1 to 2.0 mm or a range from 0.1 to 1.0 mm.

The insulating layers 713 and 714 may be made of a common insulating material, and may, for example, contain at least one selected from a group consisting of alumina (AlOx), silica (SiOx), silicon nitride (SiNx), zinc oxide (ZnOx), and zirconia (ZrOx). Specifically, the insulating layers 713 and 714 may contain at least one selected from a group consisting of alumina (Al₂O₃), silica (SiO₂), silicon nitride (Si₃N₄), zinc oxide (ZnO), and zirconia (ZrO₂). In addition, the insulating layers 713 and 714 may have an average thickness in a range from 0.05 to 2.0 mm or a range from 0.1 to 1.0 mm.

The conductive layers 714 and 724 may be made of a common conductive metal material. For example, the conductive layers 714 and 724 may contain at least one selected from a group consisting of copper (Cu), aluminum (Al), zinc (Zn), and nickel (Ni). In addition, the conductive layers 714 and 724 may have an average thickness in a range from 0.01 to 0.5 mm or a range from 0.01 to 0.20 mm.

The sixth oxidation preventing layer 715 and the fifth oxidation preventing layer 725 are the same as described in the first oxidation preventing layer to the fourth oxidation preventing layer.

In the thermoelectric module, the first electrode and the second electrode may be electrically connected to a power supply. For example, when a DC voltage is applied from the outside, a basic current starts to flow and holes of the P-type thermoelectric element and electrons of the N-type thermoelectric element move, so that exothermic and endothermic reactions may occur at both ends of the thermoelectric element.

In addition, in the thermoelectric module, for example, at least one of the first electrode and the second electrode may be exposed to a heat source. When the thermoelectric module is supplied with heat by the heat source, as electrons and holes move, current flows to generate electricity.

In the thermoelectric module, the first electrode may be in contact with a cooling plate, and the second electrode may be in contact with the heat source. That is, the first electrode may be an electrode for a low-temperature portion, and the second electrode may be an electrode for a high-temperature portion.

The thermoelectric module according to the present disclosure as described above have excellent interlayer bonding strength, in particular, excellent bonding strength between the electrode and the substrate, and excellent thermal durability as the interlayer bonding strength is superior to the thermal stress generated when exposed to the heat. For this reason, as the thermoelectric module has the excellent durability to withstand thermal shock even when exposed to the high-temperatures for a long time, the thermoelectric module may be suitably used as a material for a vehicle.

### Vehicle

The present disclosure provides a vehicle including the thermoelectric module as described above.

Hereinafter, the present disclosure is described in more detail through Examples. However, such Examples are only for helping the understanding of the present disclosure, and the scope of the present disclosure is not limited to such Examples in any sense.

### EXAMPLES

### Example 1. Manufacturing of Thermoelectric Module

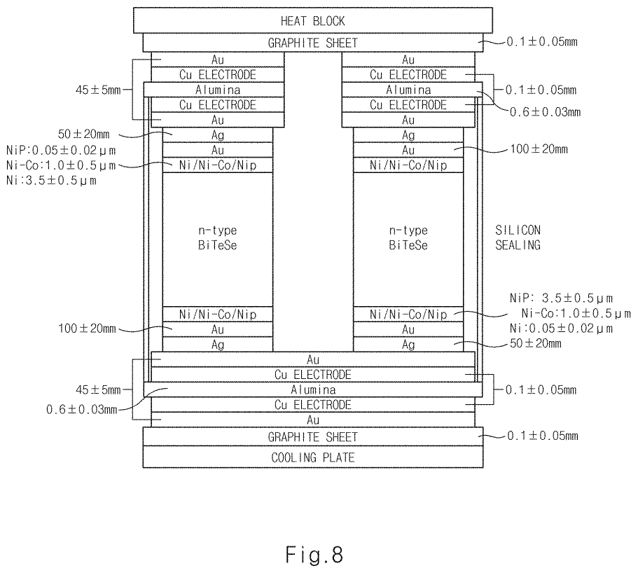

The thermoelectric module was manufactured with the same structure and thickness as in FIG. 8.

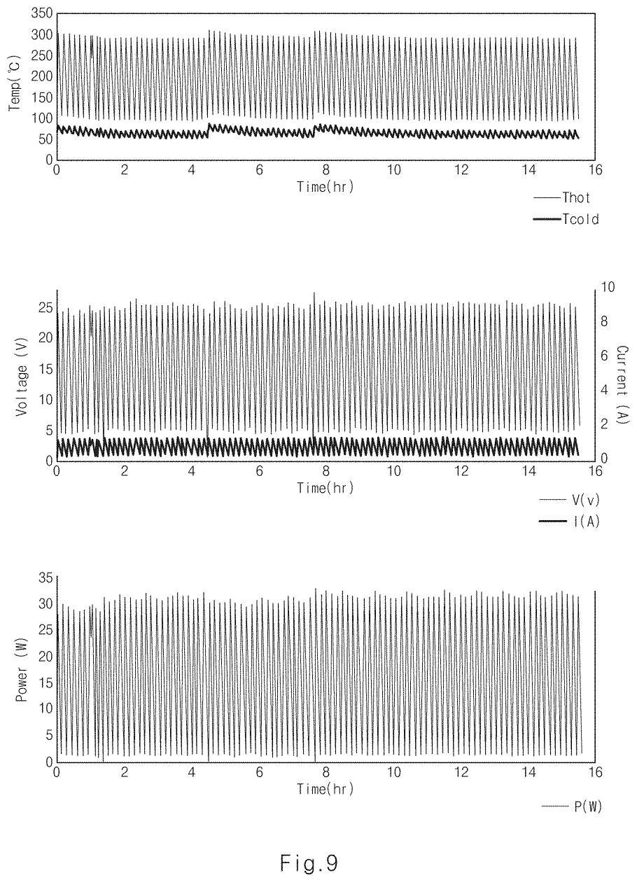

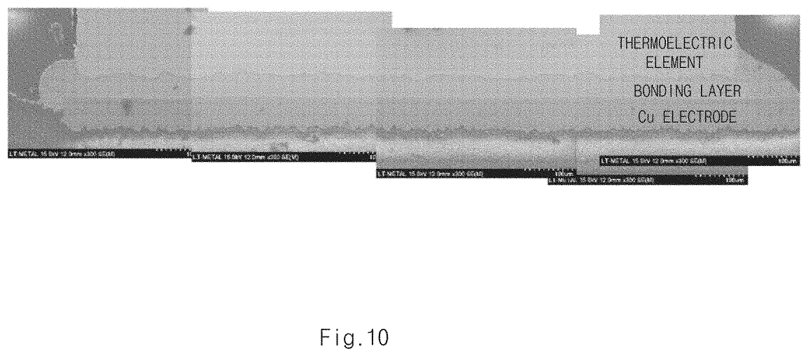

Afterwards, for the thermoelectric module, the cooling plate, which is the low-temperature portion, was maintained at 85±5° C., and a hot block, which is the high-temperature portion, was subjected to a total of 100 thermal shocks using changes in temperature between 100° C. and 300° C. for 10 minutes as one cycle. In this connection, Tₕₒₜ, which is a temperature of a graphite sheet on a side of the hot block, T_{cold}, which is a temperature of a graphite sheet on a side of the cooling plate, and a voltage, a current, and an output of the thermoelectric module were measured, and a measurement result is shown in FIG. 9. In FIG. 9, V is the measured voltage, and a unit thereof is volts (v). I is the measured current, and a unit thereof is amperes (A). In addition, P is measured power, and a unit thereof is watts (w). In addition, an interface of each layer was observed by scanning electron microscopy (SEM) after the thermal shock test, and an observation result is shown in FIG. 10.

As shown in FIG. 9, it may be seen from the result of the thermal shock test in which the temperature of the high-temperature portion repeats the rise and fall that the thermoelectric module of the present disclosure has the excellent durability as the voltage, the current, and the output are all kept constant even after multiple thermal shocks.

As shown in FIG. 10, it may be seen that the durability is excellent as no cracks were found between the thermoelectric element and the bonding layer and/or between the bonding material and a Cu electrode.

### Comparative Example 1

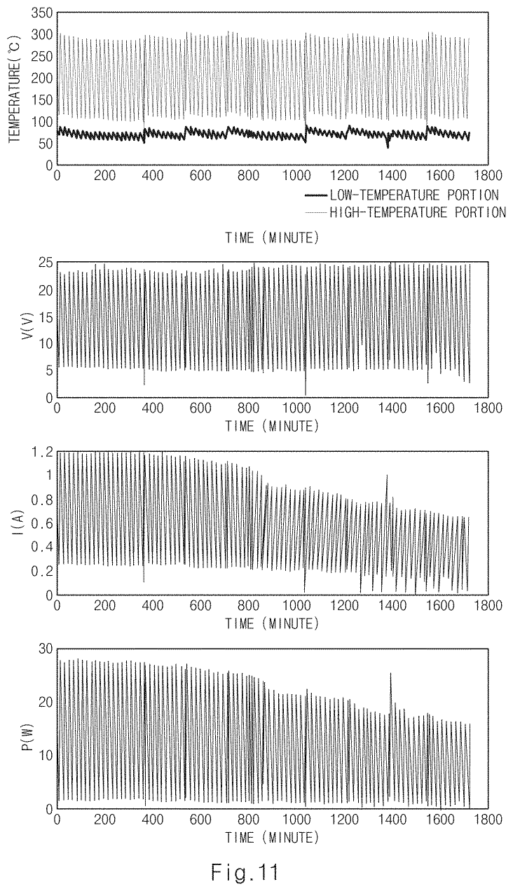

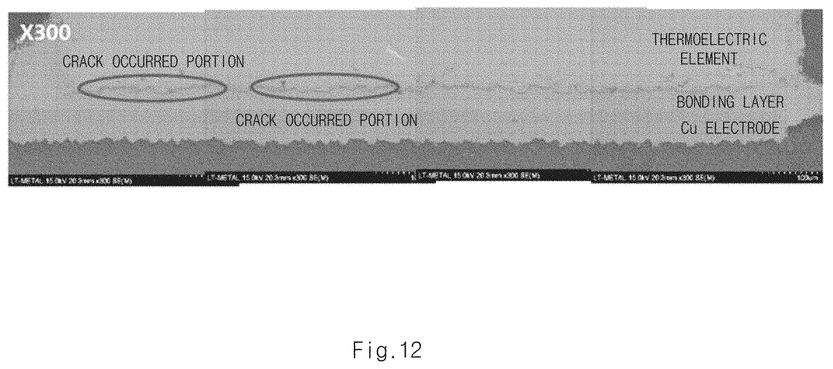

Except for using AgSn instead of Ag as the bonding layer, the thermoelectric module was manufactured in the same manner as in Example 1. After performing the thermal shock test in the same manner as in Example 1, Tₕₒₜ, which is the temperature of the graphite sheet on the side of the hot block, T_{cold}, which is the temperature of the graphite sheet on the side of the cooling plate, and the voltage, the current, and the output of the thermoelectric module were measured, and a measurement result is shown in FIG. 11. In FIG. 11, V is the measured voltage, and the unit thereof is volts (v). I is the measured current, and the unit thereof is amperes (A). In addition, P is the measured power, and the unit thereof is watts (w). In addition, an interface of each layer was observed by the SEM after the thermal shock test, and an observation result is shown in FIG. 12.

As shown in FIG. 11, as the result of the thermal shock test in which the temperature of the high-temperature portion repeats the rise and fall, the voltage was maintained, but the current decreased, and thus the output decreased as the number of thermal shocks increases. It may be seen that a performance of the material was maintained because of the maintenance of the voltage, and a resistance was increased at the interface of each layer because of the decrease in the current.

As shown in FIG. 12, it was identified that the cracks occurred between the thermoelectric element and the bonding layer. As a result, it may be seen that the interfacial resistance increased, and thus the current decreased as shown in FIG. 11.

### Comparative Example 2

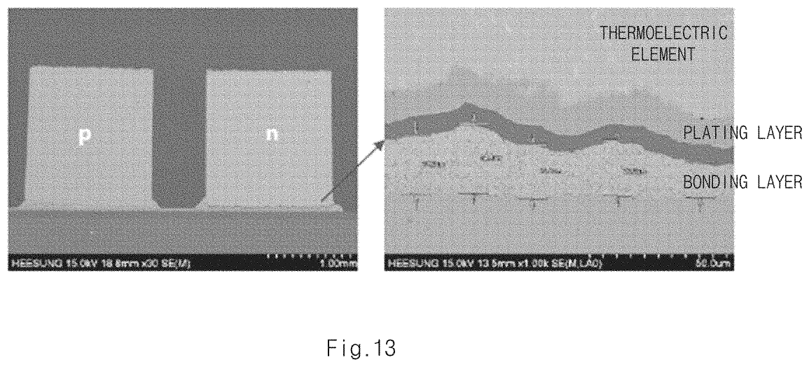

Except for not forming the oxidation preventing layer containing gold (Au) between the plating layer and the bonding layer, the thermoelectric module was manufactured in the same manner as in Example 1. After performing the thermal shock test in the same manner as in Example 1, the interface of each layer was observed by the SEM, and an observation result is shown in FIG. 13.

As shown in FIG. 13, because of insufficient bonding force between the bonding layer and the plating layer, the interlayer interface was peeled off after the thermal shock test, resulting in a short circuit.

### Comparative Example 3

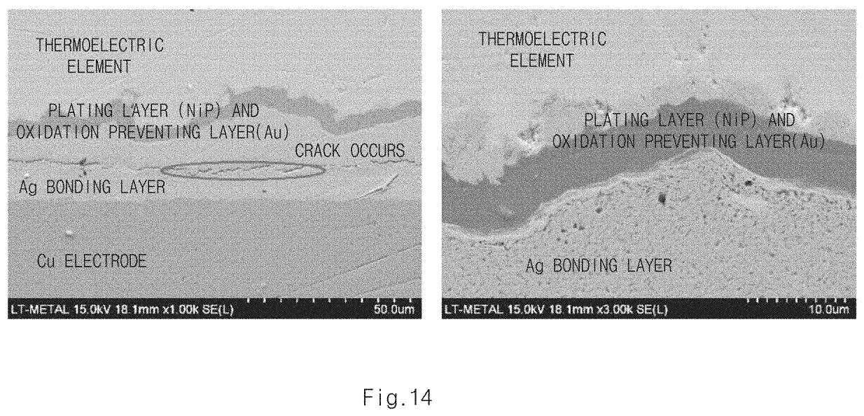

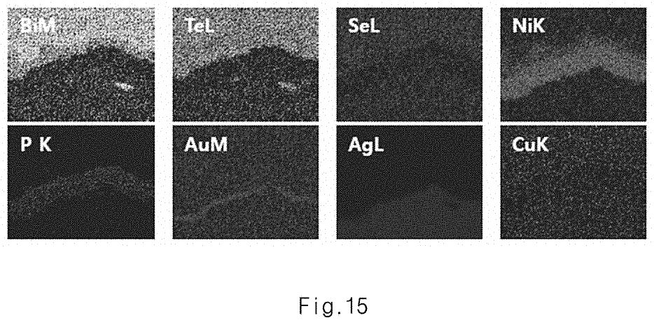

Except for applying only NiP as the plating layer, the thermoelectric module was manufactured in the same manner as in Example 1. After performing the thermal shock test in the same manner as in Example 1, the interface of each layer was observed by the SEM, and an observation result is shown in FIG. 14. In addition, interfaces of the thermoelectric element, the plating layer, and the oxidation preventing layer were observed by energy-dispersive X-ray spectroscopy (EDS), and an observation result is shown in FIG. 15.

As shown in FIG. 14, the cracks occurred inside the bonding layer, and a large number of pores were defined inside the bonding layer, resulting in reduced durability.

As shown in FIG. 15, it may be seen from a graph for identifying NiK that nickel (Ni) of the plating layer was diffused into the thermoelectric element. Such changes in composition within the thermoelectric element may cause degradation of a performance of the thermoelectric module.

The thermoelectric module according to the present disclosure have the excellent interlayer bonding strength, in particular, the excellent bonding strength between the electrode and the substrate, and the excellent thermal durability as the interlayer bonding strength is superior to the thermal stress generated when exposed to heat. For this reason, as the thermoelectric module has the excellent durability to withstand the thermal shock even when exposed to the high-temperatures for the long time, the thermoelectric module may be suitably used as the material for the vehicle.

Hereinabove, the present disclosure has been described with reference to embodiments and the accompanying drawings. However, the present disclosure is not limited thereto and may be variously modified and altered by those having ordinary skill in the art to which the present disclosure pertains without departing from the spirit and scope of the present disclosure claimed in the following claims.

What is claimed is:

1. A thermoelectric module comprising:
a first electrode;
a first oxidation preventing layer stacked on one surface of the first electrode;
a plurality of first bonding layers stacked on the first oxidation preventing layer and containing silver (Ag);
a second oxidation preventing layer stacked on each first bonding layer;
a first plating layer stacked on each second oxidation preventing layer;
a thermoelectric element stacked on each first plating layer;
a second plating layer stacked on each thermoelectric element;
a third oxidation preventing layer stacked on each second plating layer;
a second bonding layer stacked on each third oxidation preventing layer and containing silver (Ag);
a fourth oxidation preventing layer stacked on each second bonding layer; and
a second electrode stacked on each fourth oxidation preventing layer,
wherein each of the first plating layer and the second plating layer includes a nickel layer, a first alloy layer stacked on the nickel layer and including a nickel-cobalt alloy, and a second alloy layer stacked on the first alloy layer and including a nickel-phosphorus alloy.

2. The thermoelectric module of claim 1, wherein each of the first oxidation preventing layer to the fourth oxidation preventing layer independently contains at least one selected from a group consisting of gold (Au), silver (Ag), titanium (Ti), chromium (Cr), nickel (Ni), tantalum (Ta), platinum (Pt), and aluminum (Al).

3. The thermoelectric module of claim 1, wherein each of the first oxidation preventing layer to the fourth oxidation preventing layer independently has a thickness in a range from 5 to 500 nm.

4. The thermoelectric module of claim 1, wherein each of the first plating layer and the second plating layer independently includes the nickel layer having a thickness in a range from 0.001 to 1 μm, the first alloy layer having a thickness in a range from 0.1 to 15 μm, and the second alloy layer having a thickness in a range from 0.6 to 20 μm.

5. The thermoelectric module of claim 1, wherein each of the first plating layer and the second plating layer independently has the nickel layer having a thickness in a range from 0.1 to 5 thickness %, the first alloy layer having a thickness in a range from 1 to 90 thickness %, and the second alloy layer having a thickness in a range from 1 to 90 thickness % based on a total thickness of the plating layer.

6. The thermoelectric module of claim 1, wherein each of the first bonding layer and the second bonding layer independently has a thickness in a range from 5 to 500 nm.

7. The thermoelectric module of claim 1, further comprising:
a first substrate stacked on the other surface of the first electrode; and
a second substrate stacked on each second electrode.

8. The thermoelectric module of claim 7, wherein each of the first substrate and the second substrate is independently selected from a group consisting of a metal copper clad laminate (MCCL) substrate including an insulating resin layer and a metal layer stacked on the resin layer, and a direct bonded copper (DBC) substrate including an insulating layer.

9. The thermoelectric module of claim 8, wherein the resin layer contains at least one selected from a group consisting of alumina and an epoxy resin,
wherein the metal layer contains at least one selected from a group consisting of aluminum (Al), copper (Cu), nickel (Ni), silver (Ag), and chromium (Cr).

10. The thermoelectric module of claim 8, wherein the insulating layer contains at least one selected from a group consisting of alumina, silica, silicon nitride, zinc oxide, and zirconia.

11. The thermoelectric module of claim 1, wherein each of the first electrode and the second electrode independently has a thickness in a range from 10 to 500 μm.

12. The thermoelectric module of claim 1, wherein each of the first electrode and the second electrode independently contains at least one selected from a group consisting of aluminum (Al), zinc (Zn), copper (Cu), nickel (Ni), silver (Ag), and chromium (Cr).

13. A vehicle comprising the thermoelectric module of one of claim 1.
